(19) United States
(12) Patent Application Publication
(10) Pub. No.: US 2015/0214435 A1
(43) Pub. Date: Jul. 30, 2015

(54) SEMICONDUCTOR LIGHT EMITTING DIODE DEVICE AND FORMATION METHOD THEREOF

(71) Applicant: HANGZHOU SILAN AZURE CO., LTD, HANGZHOU, ZHEJIANG (CN)

(72) Inventors: Haoxiang Zhang, Hangzhou (CN); Yuzhe Jin, Hangzhou (CN); Feifei Feng, Hangzhou (CN); Yuantao Wan, Hangzhou (CN); Dongsheng Li, Hangzhou (CN); Zhongyong Jiang, Hangzhou (CN)

(73) Assignee: HANGZHOU SILAN AZURE CO., LTD, HANGZHOU, ZHEJIANG (CN)

(21) Appl. No.: 14/406,554

(22) PCT Filed: Sep. 21, 2012
(86) PCT No.: PCT/CN2012/081724

§ 371 Date: Apr. 3, 2015

(30) Foreign Application Priority Data
Apr. 27, 2012 (CN) 201210130161.3

(51) Int. Cl. H01L 33/40; H01L 33/32; H01L 33/00

(52) U.S. Cl. CPC H01L 33/40; H01L 33/0066; H01L 33/0075; H01L 33/0079; H01L 33/32; H01L 2933/0016

(57) ABSTRACT

The present invention provides a semiconductor light emitting diode (LED) device and a formation method thereof. The device comprises: an active layer; a P-type semiconductor layer and an N-type semiconductor layer respectively located at two sides of the active layer; a positive electrode welding layer electrically connected to the P-type semiconductor layer; and a negative electrode welding layer electrically connected to the N-type semiconductor layer. The material of the positive electrode welding layer and/or the negative electrode welding layer is an aluminum alloy material. The present invention is capable of better meeting requirements of the LED device for the electrode welding layers, improving electro-migration resistance under large current, and improving the thermal stability of the device. Compared with a conventional aluminum material, the service life of the device is increased, and control over industrialization cost is facilitated.

### FIELD

The present invention relates to a semiconductor light emitting diode device and a formation method thereof.

### BACKGROUND

Recently, a Group III-V compound semiconductor light emitting diode (LED) has attracted more attentions. As LED products have been increasingly launched to the market, the price of chips and lamps both drops with a drop range of 20-30% in average. The technology critical to the Group III-V compound semiconductor light emitting diode includes the growth of an epitaxial wafer and the fabrication of electrodes of the chips.

In order to further decrease the manufacturing cost of the LED, those skilled in the art have currently attempted to utilize silicon and metal materials as the substrate material for developing a high-power LED. However, as the manufacturing cost of a sapphire substrate continuously drops, the cost advantage of the silicon and metal materials has not been obvious. However, regarding the silicon and other substrate materials, a process of substrate transfer is still necessary afterwards due to light absorption, which results in the decrease of the manufacturing yield. For the fabrication of electrodes of the chips, a P electrode and an N electrode must be fabricated to contact with their respective P-type and N-type semiconductor layer in order for the Group III-V compound semiconductor device with the property of a PN junction to emit light because the sapphire substrate is an insulator.

The LED chips may be divided into a vertical structure and a plane structure according to the paths along which the current flows in operation. The conventional process of a chip with the plane structure includes: growing an N-type gallium nitride, an active layer, a P-type gallium nitride sequentially on the sapphire substrate; etching part of the P-type gallium nitride and the active layer by dry etching to expose the N-type gallium nitride; and fabricating the electrodes on the P-type gallium nitride and the N-type gallium nitride, so as to form the LED chip with the horizontal structure. The process of a chip with the vertical structure includes: placing an epitaxial layer on a conductive substrate such that the current flows up and down. Moreover, the chips may also be divided into a normal structure and a flip structure according to the out-light surfaces of the LED, in which for the normal structure, the light exits from a P surface, while for the flip structure, the light exits from an N surface.

The electrodes in the LED device must meet the following requirements: (1) the voltage drop on the electrodes is small and the resistivity of the metal is low; (2) the ohmic contact resistance between the N-type and P-type semiconductors is low; (3) the electrodes should have a certain light permeability or reflectivity; (4) the ability of electro-migration resistance under a high temperature and a large current is strong; (5) the ability of electro-chemical corrosion resistance is strong; (6) easy to bond; (7) the process of film deposition and photolithography patterning are simple; and (8) the cost thereof is low. The mature processes in the prior art usually employ NiAu and ITO as an extended electrode of an anode because such electrode has good permeability of visible wavelength and a lower contact resistance with the P-type compound semiconductor layer. So far, people pay all attention to the structure and the material of the device in order to improve the brightness and performance of the light emitting diode, while the manufacturing cost is continuously decreased.

The existing Group III-V semiconductor photoelectric device employs a simple metal such as Al, Ni, Cr, Ti, Pt, Au, etc. to form the electrodes. As the LED penetrates into the general lighting field, a high-brightness and high-power photoelectric device comes up, in which larger size and higher heat propose higher requirements to the chip processes. Since the extension of a surface current of the large-size chip has an important effects on both heat distribution and light distribution on the chip surface, large-range electrode distribution is advantageous to the current distribution. Golden or aluminum is widely utilized in various power chips as a main material of the electrodes due to its low resistivity. However, aluminum is not suitable for the electrode material of large-current and high-power chips due to its lower melting point (660° C.) and higher electro-migration. The price of golden is high, the golden layer electrode is generally fabricated with a thickness greater than 1 μm, and evaporating thick enough gold will result in larger consumption of the golden material. Due to the application and continuous development of the LED and the continuous increase of the price of golden as an expensive metal material, the reduced space for the cost of such parts is smaller, which is not good for the decrease of the cost of LED device.

The following chart shows the comparison of parameters of various electrode materials:

| | Melting Point | Resistivity | Work Function |
|---|---|---|---|
| Material | ° C. | μΩ-cm | eV |
| Si | 1412 | 10⁹ | 4.85 |
| Al | 660 | 2.65 | 4.28 |
| Ag | 961 | 1.58 | 4.26 |
| Cu | 1083 | 1.678 | 4.65 |
| W | 3417 | 8 | 4.55 |
| Ti | 1670 | 60 | 4.33 |
| Ta | 2996 | 14.5 | 4.25 |
| Mo | 2620 | 5 | 4.6 |
| Cr | 1857 | 6.83 | 4.5 |
| Ni | 1453 | 6.84 | 5.15 |

As seen from the chart above, similar to aluminum and golden, the material such as silicon, copper, tungsten, etc. is not the ideal material for the LED electrodes due to the limitation on parameters such as the resistivity, the melting point, etc.

### SUMMARY

The technical problems to be solved by the present invention is to provide a semiconductor light emitting diode device and a formation method thereof, which is capable of better meeting the requirements of a LED device for an electrode welding layer.

In order to solve the technical problem as described above, the present invention provides a semiconductor light emitting diode device, including:

an active layer;

a P-type semiconductor layer and an N-type semiconductor layer respectively located at two sides of said active layer;

a positive electrode welding layer electrically connected to said P-type semiconductor layer; and

a negative electrode welding layer electrically connected to said N-type semiconductor layer;

wherein the material of said positive electrode welding layer and/or said negative electrode welding layer is an aluminum alloy material.

Optionally, the content of aluminum element in said aluminum alloy material is equal to or greater than 50% and less than 100%.

Optionally, the content of aluminum element in said aluminum alloy material is equal to or greater than 90% and less than 100%.

Optionally, said aluminum alloy material is a binary alloy composed of aluminum and one of the following: boron, calcium, magnesium, germanium and silicon.

Optionally, in said aluminum alloy material, the content of boron, calcium, magnesium, germanium or silicon is 0.1˜5 wt %, and the rest is that of aluminum.

Optionally, said aluminum alloy material is an aluminum alloy material formed of aluminum and one or more elements of Group IVB, Group VB, Group VIB, Group VIIB, Group IB and Group VIII.

Optionally, in said aluminum alloy material, the total content of one or more elements of Group IVB, Group VB, Group VIB, Group VIIB, Group IB and Group VIII is 0.1˜5 wt %, and the rest is that of aluminum.

Optionally, said aluminum alloy material is an aluminum alloy material formed of boron, calcium, magnesium, germanium or silicon, one or more elements of Group IVB, Group VB, Group VIB, Group VIIB, Group IB and Group VIII, and aluminum.

Optionally, in said aluminum alloy material, the content of boron, calcium, magnesium, germanium or silicon is 0.1˜5 wt %, the total content of one or more elements of Group IVB, Group VB, Group VIB, Group VIIB, Group IB and Group VIII is 0.1˜5 wt %, and the rest of that is aluminum.

Optionally, said N-type semiconductor layer is an N-type doped Group III-V compound semiconductor layer, and said P-type semiconductor layer is a P-type doped Group III-V compound semiconductor layer.

Optionally, said positive electrode welding layer and said negative electrode welding layer are located at the same side or different sides of said semiconductor light emitting diode device.

Optionally, said semiconductor light emitting diode device further includes: an extended electrode layer located on said P-type semiconductor layer and contacting with said P-type semiconductor layer, said positive electrode welding layer being located on said extended electrode layer and contacting with said extended electrode layer.

Optionally, said semiconductor light emitting diode device further includes: an extended electrode layer located on said P-type semiconductor layer and contacting with said P-type semiconductor layer, and a positive electrode contact layer located on said extended electrode layer and contacting with said extended electrode layer, said positive electrode welding layer being located on said positive electrode contact layer and contacting with said positive electrode contact layer.

Optionally, said semiconductor light emitting diode device further includes: an extended electrode layer located on said P-type semiconductor layer and contacting with said P-type semiconductor layer, a positive electrode contact layer located on said extended electrode layer and contacting with said extended electrode layer, and a positive electrode transition layer located on said positive electrode contact layer and contacting with said positive electrode contact layer, said positive electrode welding layer being located on said positive electrode transition layer and contacting with said positive electrode transition layer.

Optionally, said semiconductor light emitting diode device further includes: a negative electrode contact layer located on said N-type semiconductor layer and contacting with said N-type semiconductor layer, said negative electrode welding layer being located on said negative electrode contact layer and contacting with said negative electrode contact layer.

Optionally, said semiconductor light emitting diode device further includes: a negative electrode contact layer located on said N-type semiconductor layer and contacting with said N-type semiconductor layer, and a negative electrode transition layer located on said negative electrode contact layer and contacting with said negative electrode contact layer, said negative electrode welding layer being located on said negative electrode transition layer and contacting with said negative electrode transition layer.

Optionally, the plane area of said active layer is greater than 100 square mil.

Optionally, the plane area of said active layer is greater than 300 square mil.

Optionally, the plane area of said active layer is selected from 576 square mil, 800 square mil, 1444 square mil, 1600 square mil, 2025 square mil and 3600 square mil.

Optionally, a working current of said semiconductor light emitting diode device is greater than 20 mA and less than 1 A.

Optionally, a working current of said semiconductor light emitting diode device is a forward working current of 350 mA, 500 mA, 500 mA or 1 A.

Optionally, the thickness of said positive electrode welding layer and said negative electrode welding layer is 0.1˜10 μm.

Optionally, said aluminum alloy material is alloy composed of aluminum and silicon. Optionally, in said aluminum alloy material, the content of silicon is 0.1˜5 wt % and the rest is that of aluminum.

Optionally, said aluminum alloy material is alloy composed of aluminum and copper.

Optionally, in said aluminum alloy material, the content of copper is 0.1˜5 wt % and the rest is that of aluminum.

Optionally, said aluminum alloy material is alloy composed of aluminum, silicon and copper.

Optionally, in said aluminum alloy material, the total content of silicon and copper is 0.1˜5 wt % and the rest is that of aluminum.

The present invention also provides a method for forming a semiconductor light emitting diode device, including:

sequentially forming an N-type semiconductor layer, an active layer and a P-type semiconductor layer on a sapphire substrate;

forming a positive electrode welding layer and a negative electrode welding layer, said positive electrode welding layer being electrically connected to said P-type semiconductor layer and said negative electrode welding layer being electrically connected to said N-type semiconductor layer;

wherein a material of said positive electrode welding layer and/or said negative electrode welding layer is an aluminum alloy material.

Optionally, the content of an aluminum element in said aluminum alloy material is equal to or greater than 50% and less than 100%.

Optionally, the content of an aluminum element in said aluminum alloy material is equal to or greater than 90% and less than 100%.

Optionally, said aluminum alloy material is a binary alloy composed of aluminum and one of the following: boron, calcium, magnesium, germanium and silicon.

Optionally, in said aluminum alloy material, the content of boron, calcium, magnesium, germanium or silicon is 0.1˜5 wt %, and the rest is that of aluminum.

Optionally, said aluminum alloy material is an aluminum alloy material formed of aluminum and one or more elements of Group IVB, Group VB, Group VIB, Group VIIB, Group IB and Group VIII.

Optionally, in said aluminum alloy material, the total content of one or more elements of Group IVB, Group VB, Group VIB, Group VIIB, Group IB and Group VIII is 0.1˜5 wt %, and the rest is that of aluminum.

Optionally, said aluminum alloy material is an aluminum alloy material formed of boron, calcium, magnesium, germanium or silicon, one or more elements of Group IVB, Group VB, Group VIB, Group VIIB, Group IB and Group VIII, and aluminum.

Optionally, in said aluminum alloy material, the content of boron, calcium, magnesium, germanium or silicon is 0.1˜5 wt %, the total content of one or more elements of Group IVB, Group VB, Group VIB, Group VIIB, Group IB and Group VIII is 0.1˜5 wt %, and the rest is that of aluminum.

Optionally, said N-type semiconductor layer is an N-type doped Group III-V compound semiconductor layer, and said P-type semiconductor layer is a P-type doped Group III-V compound semiconductor layer.

Optionally, forming a positive electrode welding layer and a negative electrode welding layer includes:

forming an extended electrode layer on said P-type semiconductor layer;

forming said positive electrode welding layer on said extended electrode layer;

etching said extended electrode layer, said P-type semiconductor, said active layer and said N-type semiconductor layer to form a trench, said N-type semiconductor layer being exposed at the bottom of said trench; and

forming said negative electrode welding layer on said N-type semiconductor layer at the bottom of said trench.

Optionally, after forming said N-type semiconductor layer, said active layer and said P-type semiconductor layer and before forming said positive electrode welding layer and said negative electrode welding layer, said method further includes:

transferring said N-type semiconductor layer, said active layer and said P-type semiconductor layer onto a transferring substrate, and peeling said sapphire substrate, wherein said P-type semiconductor layer is close to said transferring substrate;

forming a positive electrode welding layer and a negative electrode welding layer includes:

forming said negative electrode welding layer on said N-type semiconductor layer; and

forming said positive electrode welding layer on said transferring substrate, said positive electrode welding layer and said negative electrode welding layer being located at different sides of said semiconductor light emitting diode device.

Optionally, the thickness of said positive electrode welding layer and said negative electrode welding layer is 0.1˜10 μm.

Optionally, the plane area of said active layer is greater than 100 square mil.

Optionally, a working current of said semiconductor light emitting diode device is greater than 20 mA and less than 1 A.

Optionally, a working current of said semiconductor light emitting diode device is a forward working current of 350 mA, 500 mA, 500 mA or 1 A.

Optionally, said aluminum alloy material is alloy composed of aluminum and silicon. Optionally, in said aluminum alloy material, the content of silicon is 0.1˜5 wt % and the rest is that of aluminum.

Optionally, said aluminum alloy material is alloy composed of aluminum and copper.

Optionally, in said aluminum alloy material, the content of copper is 0.1˜5 wt % and the rest is that of aluminum.

Optionally, said aluminum alloy material is alloy composed of aluminum, silicon and copper.

Optionally, in said aluminum alloy material, the total content of silicon and copper is 0.1˜5 wt % and the rest is that of aluminum.

Compared with the prior art, the present invention has the following advantages:

in the semiconductor light emitting diode device and a formation method thereof according to embodiments of the present invention, the material of the positive electrode welding layer and/or the negative electrode welding layer is an aluminum alloy material, being capable of improving electro-migration resistance under a large current, improving the thermal stability of the device, increasing the service life of the device compared with a conventional aluminum material, and facilitating the control over industrialization cost.

### BRIEF DESCRIPTION OF THE DRAWINGS

FIG. 1 is a schematic cross-section diagram of a semiconductor light emitting diode device according to the first embodiment and the second embodiment of the present invention;

FIG. 2 is a schematic cross-section diagram of a semiconductor light emitting diode device according to the third embodiment of the present invention;

FIG. 3 is a schematic cross-section diagram of a semiconductor light emitting diode device according to the fourth embodiment of the present invention;

FIG. 4 is a schematic cross-section diagram of a semiconductor light emitting diode device according to the fifth embodiment of the present invention.

### DETAILED DESCRIPTION

Hereafter, the further description is made to the present invention in light of the specific embodiments and the accompanying drawings, but the scope of the present invention is not limited thereto.

### A First Embodiment

FIG. 1 illustrates a cross-section of a semiconductor light emitting diode device according to the first embodiment. The semiconductor light emitting diode device includes: a substrate 10; an N-type semiconductor layer 2, an active layer 3 and a P-type semiconductor layer 4 sequentially located on the substrate 10; an extended electrode layer 5 located on the P-type semiconductor layer 4; a positive electrode welding layer 61 located on the extended electrode layer 5; a trench located in the P-type semiconductor layer 4, the active layer 3 and the N-type semiconductor layer 2, the N-type semiconductor layer 2 being exposed at the bottom of the trench; and a negative electrode welding layer 62 located at the bottom of the trench. In this embodiment, the positive electrode welding layer 61 and the negative electrode welding layer 62 are located at the same side of the whole semiconductor light emitting diode device.

Wherein the substrate 10 may be a sapphire substrate. The N-type semiconductor layer 2 may be an N-type doped Group III-V compound semiconductor layer (e.g., gallium nitride). The P-type semiconductor layer 4 may be a P-type doped Group III-V compound semiconductor layer (e.g., gallium nitride). The material of the extended electrode layer 5 may be ITO, etc.

The thickness of the positive electrode welding layer 61 and the negative electrode welding layer 62 is 0.1˜10 μm, the material of one or both of which is an aluminum alloy material. In this aluminum alloy material, the content of the aluminum element is equal to or greater than 50% and less than 100%. Preferably, the content of the aluminum element is equal to or greater than 90% and less than s100%.

Alternatively, this aluminum alloy material may be a binary alloy composed of aluminum and boron, calcium, magnesium, germanium or silicon and, in which the content of boron, calcium, magnesium, germanium or silicon is 0.1˜5 wt %, and the rest is that of aluminum.

Alternatively, this aluminum alloy material may be an aluminum alloy material formed of aluminum and one or more elements of Group IVB, Group VB, Group VIB, Group VIIB, Group IB and Group VIII, in which the total content of one or more elements of Group IVB, Group VB, Group VIB, Group VIIB, Group IB and Group VIII is 0.1˜5 wt %, and the rest is that of aluminum.

Alternatively, this aluminum alloy material may be an aluminum alloy material formed of aluminum, one element of boron, calcium, magnesium, germanium and silicon, and one or more elements of Group IVB, Group VB, Group VIB, Group VIIB, Group IB and Group VIII, in which the content of boron, calcium, magnesium, germanium or silicon is 0.1˜5 wt %, the total content of one or more elements of Group IVB, Group VB, Group VIB, Group VIIB, Group IB and Group VIII is 0.1˜5 wt %, and the rest is that of aluminum.

Preferably, the aluminum alloy material employed by the positive electrode welding layer 61 and the negative electrode welding layer 62 is alloy composed of aluminum and silicon, in which the content of silicon is 0.1˜5 wt % and the rest is that of aluminum. Alternatively, such aluminum alloy material is alloy composed of aluminum and copper in which the content of copper is 0.1˜5 wt % and the rest is aluminum. Alternatively, such aluminum alloy material is alloy composed of aluminum, silicon and copper, in which the total content of silicon and copper is 0.1˜5 wt % and the rest is aluminum.

The plane area of the active layer 3 is greater than 100 square mil, preferably greater than 300 square mil. For example, the plane area of the active layer 3 may be selected from 576 square mil, 800 square mil, 1444 square mil, 1600 square mil, 2025 square mil and 3600 square mil.

A working current of the semiconductor light emitting diode device is greater than 20 mA and less than 1 A. For example, such working current may be a forward working current of 350 mA, 500 mA, 500 mA or 1 A.

In this embodiment, the thickness of the positive electrode welding layer 61 and the negative electrode welding layer 62 is specifically 2 μm, and the material thereof is aluminum alloy of Al-1 wt % Si-0.5 wt % Cu. The plane area of the active layer 3 is 576 square mil, and the forward voltage thereof is 3.2 V when the working current is 150 mA.

For the semiconductor light emitting diode device in the first embodiment, the formation method thereof may include: sequentially forming the N-type semiconductor layer 2, the active layer 3 and the P-type semiconductor layer 4 on the substrate 10; depositing the extended electrode layer 5 on the P-type semiconductor layer 4; forming the positive electrode welding layer 61 on the extended electrode layer 5; etching the extended electrode layer 5, the P-type semiconductor layer 4, the active layer 3 and the N-type semiconductor layer 2 to form a trench, the N-type semiconductor layer 2 being exposed at the bottom of this trench; and forming the negative electrode welding layer 62 on the N-type semiconductor layer 2 at the bottom of the trench. Wherein the method for forming the positive electrode welding layer 61 the negative electrode welding layer 62 is magnetron sputtering method, electron beam evaporating method, laser pulse depositing method or spraying method, preferably magnetron sputtering method in this embodiment. The specific process parameters are shown in the following chart:

Sputtering Conditions

| | |
|---|---|
| Power | 8 kW |
| Distance between a | 7 cm |
| Target and a Wafer | |
| Pressure of Argon Gas | 56 mt |
| Depositing Time | 220 sec |
| Thickness of a Film | Five-point Method |
| (within the Wafer) | (up, middle, down, left and right) |
| Range Within the Wafer | 100 nm |

### A Second Embodiment

The second embodiment describes a structure and a formation method of a semiconductor light emitting diode device similar to the first embodiment, and the differences of the second embodiment from the first embodiment are only that the thickness of the positive electrode welding layer 61 and the negative electrode welding layer 62 is 4 μm, the material thereof is aluminum alloy of Al-1 wt % Cu, the plane area of the active layer is 2025 square mil, and the forward voltage is 3.3 V when the working current is 350 mA.

### A Third Embodiment

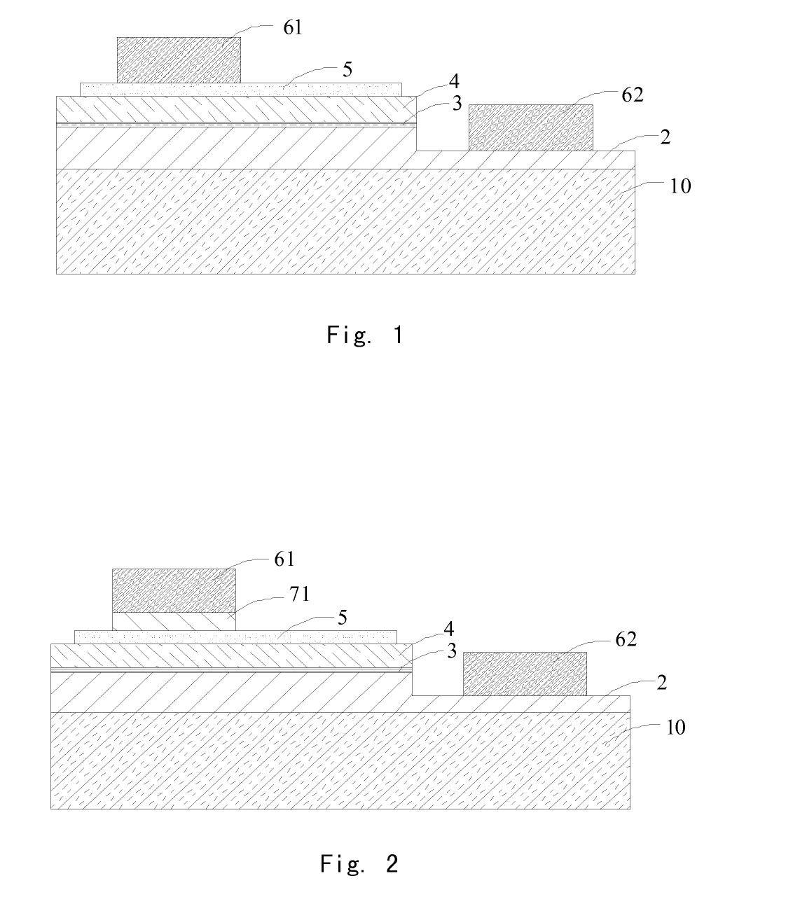

FIG. 2 illustrates a cross-section of a semiconductor light emitting diode device according to the third embodiment, in which the third embodiment describes a structure and a formation method of the semiconductor light emitting diode device similar to the first embodiment, and the differences of the third embodiment from the first embodiment are only that a positive electrode contact layer 71 is further formed on the extended electrode layer 5, the positive electrode welding layer 61 is formed on the positive electrode contact layer 71, and the positive electrode contact layer 71 can reduce the ohmic contact. Moreover, a positive electrode transition layer (now shown in the drawing) may be further formed between the positive electrode contact layer 71 and the positive electrode welding layer 61. This positive electrode transition layer may be used for blocking the diffusion reaction between the positive electrode welding layer 61 and the extended electrode layer 5, and the selectable material thereof may be Ti, Pt, Ni, W, TiW, etc.

In the third embodiment, the thickness of the positive electrode welding layer 61 and the negative electrode welding layer 62 in this semiconductor light emitting diode device is 2 μm and the material thereof is preferably aluminum alloy of Ai-1 wt % Si-0.5 wt % Cu, while the thickness of the positive electrode contact layer 71 is 5 μm and the material thereof is Ti which has good thermal stability and electro-chemical stability. The plane area of the active layer 3 is 576 square mil and the forward voltage is 3.2 V when the working current is 150 mA.

Regarding other solutions of the aluminum alloy material of the positive electrode welding layer 61 and the negative electrode welding layer 62 in the third embodiment, please refer to the relative description in the first embodiment, which is not repeated herein.

### A Fourth Embodiment

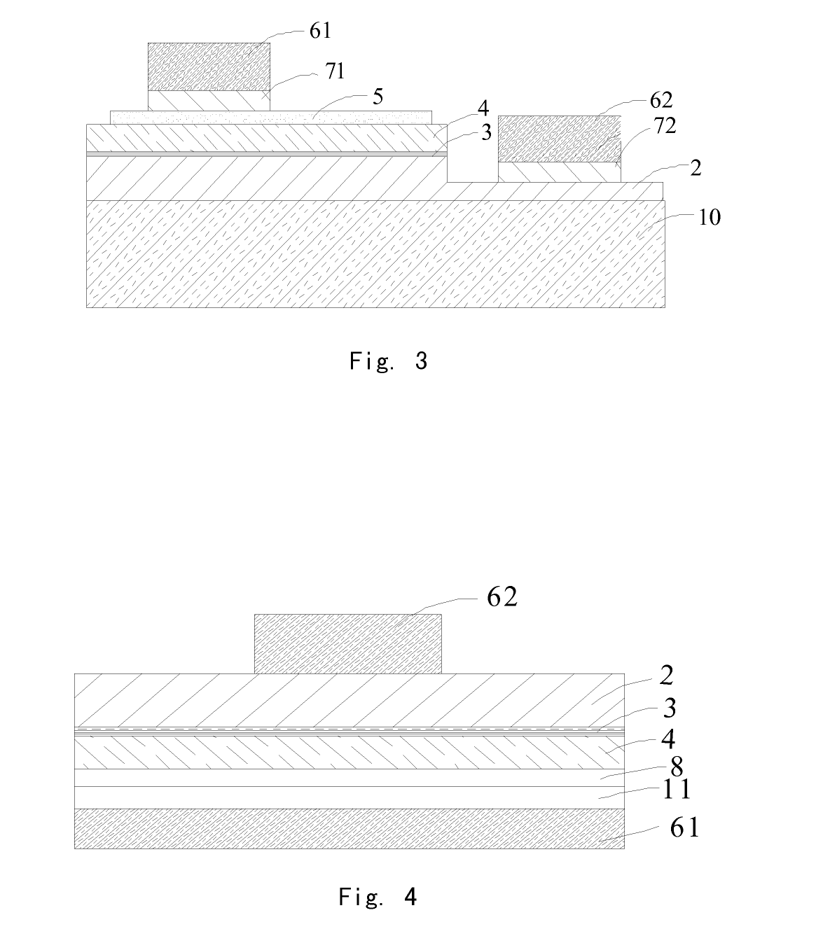

FIG. 3 illustrates a cross-section of a semiconductor light emitting diode device according to the fourth embodiment, in which the fourth embodiment describes a structure and a formation method of the semiconductor light emitting diode device similar to the first embodiment, and the differences of the fourth embodiment from the first embodiment are only that the positive electrode contact layer 71 is further formed on the extended electrode layer 5, the positive electrode welding layer 61 is formed on the positive electrode contact layer 71, the negative electrode contact layer 72 is formed on the N-type semiconductor layer 2, and the negative electrode welding layer 62 is formed on the negative electrode contact layer 72. The positive electrode contact layer 71 and the negative electrode contact layer 72 can reduce the contact resistance. Moreover, a positive electrode transition layer (now shown in the drawing) may be further formed between the positive electrode contact layer 71 and the positive electrode welding layer 61 and a negative electrode transition layer (not shown in the drawing) may be further formed between the negative electrode contact layer 72 and the negative electrode welding layer 62 so as to block the interlayer diffusion reaction. The material of the positive electrode transition layer and the negative electrode transition layer may be a metal such as Ti, Pt, Ni, W, TiW, etc.

In the fourth embodiment, the thickness of the positive electrode welding layer 61 and the negative electrode welding layer 62 in this semiconductor light emitting diode device is 4 μm and the material thereof is preferably aluminum alloy of Al-1 wt % Cu. The plane area of the active layer 3 is 2025 square mil and the forward voltage is 3.3 V when the working current is 350 mA.

Regarding other solutions of the aluminum alloy material of the positive electrode welding layer 61 and the negative electrode welding layer 62 in the fourth embodiment, please refer to the relative description in the first embodiment, which is not repeated herein.

### A Fifth Embodiment

FIG. 4 illustrates a cross-section of a semiconductor light emitting diode device according to the fifth embodiment. The semiconductor light emitting diode device includes: the active layer 3; the N-type semiconductor layer 2 and the P-type semiconductor layer 4 respectively located at two sides of the active layer 3; the negative electrode welding layer 62 contacting with the N-type semiconductor layer 2; a transferring substrate 11 connected to the P-type semiconductor layer 4 via a joining layer 8; and the positive electrode welding layer 61 contacting with the transferring substrate 11 and electrically connected to the P-type semiconductor layer 4 via the transferring substrate 11 and the joining layer 8. In other words, in this embodiment, the positive electrode welding layer 61 and the negative electrode welding layer 62 are located on different sides of the device, i.e., the device is of a vertical structure. Wherein the joining layer 8 may include a current spreading layer, a light reflecting layer, and a solder layer such as a combination of high-light-reflecting metal layer and metal solder layer or a combination of a transparent conductive layer, the high reflecting dielectric layer and the metal solder layer, which are collectively refer to as the joining layer.

The method for forming this light emitting diode device may include: sequentially forming the N-type semiconductor layer 2, the active layer 3 and the P-type semiconductor layer 4 on the sapphire substrate; transferring the N-type semiconductor layer 2, the active layer 3 and the P-type semiconductor layer 4 onto the transferring substrate 11 and peeling the sapphire substrate, wherein the P-type semiconductor layer 4 is close to the transferring substrate 11 and connected to the transferring substrate 11 via the joining layer 8, and afterwards the transferring substrate 11 may be thinned down; forming the negative electrode welding layer 62 on the N-type semiconductor layer 2; and forming the positive electrode welding layer 61 on the transferring substrate 11.

In the fifth embodiment, the material of the positive electrode welding layer 61 is preferably Al-1 wt % Si-0.5 wt % Cu and the thickness thereof is 5 μm, while the material of the negative electrode welding layer 62 is preferably Al-1 wt % Si-0.5 wt % Cu and the thickness thereof is 4 μm. This device has higher light extracting efficiency, e.g., greater than 40% when working under 350 mA and a forward voltage thereof can be up to 3.2 V. The material employed by the positive electrode welding layer 61 and the negative electrode welding layer 62 as described above can make the cost of a pedestal decreased, thermal resistance and thermal conductivity of the electrodes improved and the service life of the device extended while the voltage of the device is not decreased.

Regarding other solutions of the aluminum alloy material of the positive electrode welding layer 61 and the negative electrode welding layer 62, please refer to the relative description in the first embodiment, which is not repeated herein.

Although the present invention has been disclosed in preferable embodiments as above, the present invention is not limited thereto. Those skilled in the art may make possible variations and modifications without deviating from the spirit and scope of the present invention. Accordingly, the scope of the present invention should be defined by the claims.

1. A semiconductor light emitting diode device, comprising:
an active layer;
a P-type semiconductor layer and an N-type semiconductor layer respectively located at two sides of said active layer;
a positive electrode welding layer electrically connected to said P-type semiconductor layer;
a negative electrode welding layer electrically connected to said N-type semiconductor layer;
wherein the material of said positive electrode welding layer and/or said negative electrode welding layer is an aluminum alloy material.

2. The semiconductor light emitting diode device according to claim 1, wherein the content of aluminum element in said aluminum alloy material is equal to or greater than 50% and less than 100%.

3. The semiconductor light emitting diode device according to claim 1, wherein the content of aluminum element in said aluminum alloy material is equal to or greater than 90% and less than 100%.

4. The semiconductor light emitting diode device according to claim 1, wherein said aluminum alloy material is a binary alloy composed of aluminum and one of the following: boron, calcium, magnesium, germanium and silicon.

5. The semiconductor light emitting diode device according to claim 4, wherein in said aluminum alloy material, the content of boron, calcium, magnesium, germanium or silicon is 0.1˜5 wt %, and the rest is that of aluminum.

6. The semiconductor light emitting diode device according to claim 1, wherein said aluminum alloy material is an aluminum alloy material formed of aluminum and one or more elements of Group IVB, Group VB, Group VIB, Group VIIB, Group IB and Group VIII.

7. The semiconductor light emitting diode device according to claim 6, wherein in said aluminum alloy material, the total content of one or more elements of Group IVB, Group VB, Group VIB, Group VIIB, Group IB and Group VIII is 0.1˜5 wt %, and the rest is that of aluminum.

8. The semiconductor light emitting diode device according to claim 1, wherein said aluminum alloy material is an aluminum alloy material formed of boron, calcium, magnesium, germanium or silicon, and one or more elements of Group IVB, Group VB, Group VIB, Group VIIB, Group IB and Group VIII, and aluminum.

9. The semiconductor light emitting diode device according to claim 8, wherein in said aluminum alloy material, the content of boron, calcium, magnesium, germanium or silicon is 0.1˜5 wt %, the total content of one or more elements of Group IVB, Group VB, Group VIB, Group VIIB, Group IB and Group VIII is 0.1˜5 wt %, and the rest is that of aluminum.

10. The semiconductor light emitting diode device according to claim 1, wherein said N-type semiconductor layer is an N-type doped Group III-V compound semiconductor layer, and said P-type semiconductor layer is a P-type doped Group III-V compound semiconductor layer.

11. The semiconductor light emitting diode device according to claim 1, wherein said positive electrode welding layer and said negative electrode welding layer are located at the same side or different sides of said semiconductor light emitting diode device.

12. The semiconductor light emitting diode device according to claim 1, further comprising: an extended electrode layer located on said P-type semiconductor layer and contacting with said P-type semiconductor layer, said positive electrode welding layer being located on said extended electrode layer and contacting with said extended electrode layer.

13. The semiconductor light emitting diode device according to claim 1, further comprising: an extended electrode layer located on said P-type semiconductor layer and contacting with said P-type semiconductor layer, and a positive electrode contact layer located on said extended electrode layer and contacting with said extended electrode layer, said positive electrode welding layer being located on said positive electrode contact layer and contacting with said positive electrode contact layer.

14. The semiconductor light emitting diode device according to claim 1, further comprising: an extended electrode layer located on said P-type semiconductor layer and contacting with said P-type semiconductor layer, a positive electrode contact layer located on said extended electrode layer and contacting with said extended electrode layer, and a positive electrode transition layer located on said positive electrode contact layer and contacting with said positive electrode contact layer, said positive electrode welding layer being located on said positive electrode transition layer and contacting with said positive electrode transition layer.

15. The semiconductor light emitting diode device according to claim 12, further comprising: a negative electrode contact layer located on said N-type semiconductor layer and contacting with said N-type semiconductor layer, said negative electrode welding layer being located on said negative electrode contact layer and contacting with said negative electrode contact layer.

16. The semiconductor light emitting diode device according to claim 12, further comprising: a negative electrode contact layer located on said N-type semiconductor layer and contacting with said N-type semiconductor layer, and a negative electrode transition layer located on said negative electrode contact layer and contacting with said negative electrode contact layer, said negative electrode welding layer being located on said negative electrode transition layer and contacting with said negative electrode transition layer.

17. The semiconductor light emitting diode device according to claim 1, wherein the plane area of said active layer is greater than 100 square mil.

18. The semiconductor light emitting diode device according to claim 1, wherein the plane area of said active layer is greater than 300 square mil.

19. The semiconductor light emitting diode device according to claim 1, wherein the plane area of said active layer is selected from 576 square mil, 800 square mil, 1444 square mil, 1600 square mil, 2025 square mil and 3600 square mil.

20. The semiconductor light emitting diode device according to claim 1, wherein a working current of said semiconductor light emitting diode device is greater than 20 mA and less than 1 A.

21. The semiconductor light emitting diode device according to claim 1, wherein a working current of said semiconductor light emitting diode device is a forward working current of 350 mA, 500 mA, 500 mA or 1 A.

22. The semiconductor light emitting diode device according to claim 1, wherein the thickness of said positive electrode welding layer and said negative electrode welding layer is 0.1˜10 μm.

23. The semiconductor light emitting diode device according to claim 1, wherein said aluminum alloy material is alloy composed of aluminum and silicon.

24. The semiconductor light emitting diode device according to claim 23, wherein in said aluminum alloy material, the content of silicon is 0.1˜5 wt % and the rest is that of aluminum.

25. The semiconductor light emitting diode device according to claim 1, wherein said aluminum alloy material is alloy composed of aluminum and copper.

26. The semiconductor light emitting diode device according to claim 25, wherein in said aluminum alloy material, the content of copper is 0.1˜5 wt % and the rest is that of aluminum.

27. The semiconductor light emitting diode device according to claim 1, wherein said aluminum alloy material is alloy composed of aluminum, silicon and copper.

28. The semiconductor light emitting diode device according to claim 27, in said aluminum alloy material, the total content of silicon and copper is 0.1˜5 wt % and the rest is that of aluminum.

29. A method for forming a semiconductor light emitting diode device, comprising:
sequentially forming an N-type semiconductor layer, an active layer and a P-type semiconductor layer on a sapphire substrate;
forming a positive electrode welding layer and a negative electrode welding layer, said positive electrode welding layer being electrically connected to said P-type semiconductor layer and said negative electrode welding layer being electrically connected to said N-type semiconductor layer;
wherein a material of said positive electrode welding layer and/or said negative electrode welding layer is an aluminum alloy material.

30. The method for forming a semiconductor light emitting diode device according to claim 29, wherein the content of an aluminum element in said aluminum alloy material is equal to or greater than 50% and less than 100%.

31. The method for forming a semiconductor light emitting diode device according to claim 29, wherein the content of an aluminum element in said aluminum alloy material is equal to or greater than 90% and less than 100%.

32. The method for forming a semiconductor light emitting diode device according to claim 29, wherein said aluminum alloy material is a binary alloy composed of aluminum and one of following: boron, calcium, magnesium, germanium and silicon.

33. The method for forming a semiconductor light emitting diode device according to claim 32, wherein in said aluminum alloy material, the content of boron, calcium, magnesium, germanium or silicon is 0.1˜5 wt %, and the rest is that of aluminum.

34. The method for forming a semiconductor light emitting diode device according to claim 29, wherein said aluminum alloy material is an aluminum alloy material formed of aluminum and one or more elements of Group IVB, Group VB, Group VIB, Group VIIB, Group IB and Group VIII.

35. The method for forming a semiconductor light emitting diode device according to claim 34, wherein in said aluminum alloy material, the total content of one or more elements of Group IVB, Group VB, Group VIB, Group VIIB, Group IB and Group VIII is 0.1˜5 wt %, and the rest is that of aluminum.

36. The method for forming a semiconductor light emitting diode device according to claim 29, wherein said aluminum alloy material is an aluminum alloy material formed of boron, calcium, magnesium, germanium or silicon, and one or more elements of Group IVB, Group VB, Group VIB, Group VIIB, Group IB and Group VIII, and aluminum.

37. The method for forming a semiconductor light emitting diode device according to claim 36, wherein in said aluminum alloy material, the content of boron, calcium, magnesium, germanium or silicon is 0.1˜5 wt %, the total content of one or more elements in transition groups Group IVB, Group VB, Group VIB, Group VIIB, Group IB and Group VIII is 0.1˜5 wt %, and the rest is that of aluminum.

38. The method for forming a semiconductor light emitting diode device according to claim 29, wherein said N-type semiconductor layer is an N-type doped Group III-V compound semiconductor layer, and said P-type semiconductor layer is a P-type doped Group III-V compound semiconductor layer.

39. The method for forming a semiconductor light emitting diode device according to claim 29, wherein forming a positive electrode welding layer and a negative electrode welding layer comprising:
forming an extended electrode layer on said P-type semiconductor layer;
forming said positive electrode welding layer on said extended electrode layer;
etching said extended electrode layer, said P-type semiconductor, said active layer and said N-type semiconductor layer to form a trench, said N-type semiconductor layer being exposed at the bottom of said trench; and
forming said negative electrode welding layer on said N-type semiconductor layer at the bottom of said trench.

40. The method for forming a semiconductor light emitting diode device according to claim 29, wherein after forming said N-type semiconductor layer, said active layer and said P-type semiconductor layer and before forming said positive electrode welding layer and said negative electrode welding layer, further comprising:
transferring said N-type semiconductor layer, said active layer and said P-type semiconductor layer onto a transferring substrate, and peeling said sapphire substrate, wherein said P-type semiconductor layer is close to said transferring substrate;
forming a positive electrode welding layer and a negative electrode welding layer comprising:
forming said negative electrode welding layer on said N-type semiconductor layer;
forming said positive electrode welding layer on said transferring substrate, said positive electrode welding layer and said negative electrode welding layer being located at different sides of said semiconductor light emitting diode device.

41. The method for forming a semiconductor light emitting diode device according to claim 29, wherein the thickness of said positive electrode welding layer and said negative electrode welding layer is 0.1˜10 μm.

42. The method for forming a semiconductor light emitting diode device according to claim 29, wherein the plane area of said active layer is greater than 100 square mil.

43. The method for forming a semiconductor light emitting diode device according to claim 29, wherein a working current of said semiconductor light emitting diode device is greater than 20 mA and less than 1 A.

44. The method for forming a semiconductor light emitting diode device according to claim 29, wherein a working current of said semiconductor light emitting diode device is a forward working current of 350 mA, 500 mA, 500 mA or 1 A.

45. The method for forming a semiconductor light emitting diode device according to claim 29, wherein said aluminum alloy material is alloy composed of aluminum and silicon.

46. The method for forming a semiconductor light emitting diode device according to claim 45, wherein in said aluminum alloy material, the content of silicon is 0.1˜5 wt % and the rest is that of aluminum.

47. The method for forming a semiconductor light emitting diode device according to claim 29, wherein said aluminum alloy material is alloy composed of aluminum and copper.

48. The method for forming a semiconductor light emitting diode device according to claim 50, wherein in said aluminum alloy material, the content of copper is 0.1˜5 wt % and the rest is that of aluminum.

49. The method for forming a semiconductor light emitting diode device according to claim 29, wherein said aluminum alloy material is alloy composed of aluminum, silicon and copper.

50. The method for forming a semiconductor light emitting diode device according to claim 49, wherein in said aluminum alloy material, the total content of silicon and copper is 0.1˜5 wt % and the rest is that of aluminum.
